(19) United States
(12) Patent Application Publication
(10) Pub. No.: US 2011/0124147 A1
(43) Pub. Date: May 26, 2011

(54) METHOD FOR SEPARATING SILICON SOLAR CELLS

(75) Inventor: ROLAND MAYERHOFER, ROTTENBACH (DE)

(73) Assignee: ROFIN-BAASEL LASERTECH GMBH & CO. KG, STARNBERG (DE)

(21) Appl. No.: 13/020,972

(22) Filed: Feb. 4, 2011

Related U.S. Application Data
(63) Continuation of application No. PCT/EP2010/056708, filed on May 17, 2010.

(30) Foreign Application Priority Data
May 20, 2009 (DE) 10 2009 026 410.8

(51) Int. Cl. H01L 31/00

(52) U.S. Cl. 438/68; 257/E31.001; 257/E21.599

(57) ABSTRACT

In a method for separating silicon solar cells, a groove is introduced into a silicon wafer containing the silicon solar cells along a separating line in a front side of the silicon wafer adjacent to a p-n junction in the silicon wafer using a first laser beam. The groove has a depth reaching at least to the p-n junction and extends to a lateral edge of the silicon wafer. In a second work step, the silicon wafer is cut along the separating line starting at the lateral edge using a second laser beam directed into the groove. Wherein the melt arising during the cutting is driven out of the cutting kerf arising during the cutting using a cutting gas flowing at least approximately in the direction of the second laser beam.

### CROSS-REFERENCE TO RELATED APPLICATION

This is a continuation under 35 U.S.C. §120, of copending international application No. PCT/EP2010/056708, filed May 17, 2010, which designated the United States; this application also claims the priority, under 35 U.S.C. §119, of German patent application No. DE 10 2009 026 410.8, filed May 20, 2009; the prior applications are herewith incorporated by reference in their entirety.

### BACKGROUND OF THE INVENTION

### Field of the Invention

The invention relates to a method for separating silicon solar cells.

During the production of silicon solar cells, generally a large number of individual silicon solar cells are produced in a silicon wafer and they have to be separated from one another, i.e. singulated, in a concluding production step. In the prior art, this is done either by a mechanical sawing method or by a laser cutting method, known for example from international patent disclosure WO 2008/084206 A1. If these methods are carried out in a single stage, that is to say that if singulation is effected in a single process step, then it can happen that the individual silicon solar cells are short-circuited, particularly during laser cutting. The reason for this is that a melting zone arises in the cutting kerf, which melting zone can be enriched with doping elements. As a result, at the edge of the cutting kerf, a zone can arise in which the doping elements are mixed and the pn junction is destroyed. This can lead to a short circuit between the front side, that is to say the flat side of the solar cell in the vicinity of which the pn junction is situated, and the rear side. This problem occurs both during conventional laser cutting, in which the melt is driven out by a cutting gas flowing into the cutting kerf at high speed, and during single-stage laser cutting by a laser ablation method, in which the material escapes from the cutting kerf primarily by evaporation, and in which a Q-switched solid-state laser is generally used. Such a short circuit is also not ruled out in the case of mechanical singulation by sawing, since the metallic contact at the rear side of the silicon solar cell is likewise smeared at the cut surfaces.

In order to avoid this problem, it is known to use a two-stage process when separating silicon solar cells, in which process, in the first step, a groove is introduced into the silicon wafer by a laser beam and then the silicon wafer is broken up mechanically along these grooves.

However, the subsequent breaking of the silicon wafer requires an additional process step with a different production technology. Moreover, individual silicon solar cells can be destroyed in the course of the breaking-up process.

### SUMMARY OF THE INVENTION

It is accordingly an object of the invention to provide a method for separating silicon solar cells which overcome the above-mentioned disadvantages of the prior art methods of this general type.

In the method, in a first work step, a groove is introduced into a silicon wafer containing the silicon solar cells by a first laser beam along a separating line into a front side of the silicon wafer. The front side is adjacent to a pn junction in the silicon wafer and the groove has a depth reaching at least as far as the pn junction. The groove extends as far as a lateral edge of the silicon wafer. In a second work step, the silicon wafer is cut along the separating line by a second laser beam directed onto the groove. Wherein the melted material arising during cutting is driven out of the cutting kerf arising during cutting by a cutting gas flowing at least approximately in the direction of the second laser beam.

Since the groove extends at least into a depth of the silicon wafer at which the pn junction is situated, at most a melted material containing p-type dopant arises during laser cutting in the melting zone. Since the material is driven out in the direction of the rear side of the silicon wafer, it cannot deposit on the n-doped sidewall of the groove. A short circuit of the silicon solar cell that arises at the edge can thereby be avoided.

Particularly good results are achieved if both the first laser beam and the second laser beam are pulsed, wherein the pulse duration of the first laser beam is shorter than the pulse duration of the second laser beam. In this case, first and second laser beams can be generated either by two different lasers or by one laser, which can operate in correspondingly different operating modes.

Other features which are considered as characteristic for the invention are set forth in the appended claims.

Although the invention is illustrated and described herein as embodied in a method for separating silicon solar cells, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, plan view of a silicon wafer containing a plurality of silicon solar cells of one of its flat sides,

FIGS. 2, 4 and 6 are diagrammatic, longitudinal sectional views each showing a silicon wafer containing silicon solar cells at one of its edges along a separating line during a performance of a first work step, at a beginning of the second work step and during a performance of a second work step, respectively, and according to the invention; and

FIGS. 3, 5 and 7 are plan views showing a work step respectively corresponding to FIGS. 1, 3 and 5, in a direction of the separating line, of a narrow side of the silicon wafer.

### DETAILED DESCRIPTION OF THE INVENTION

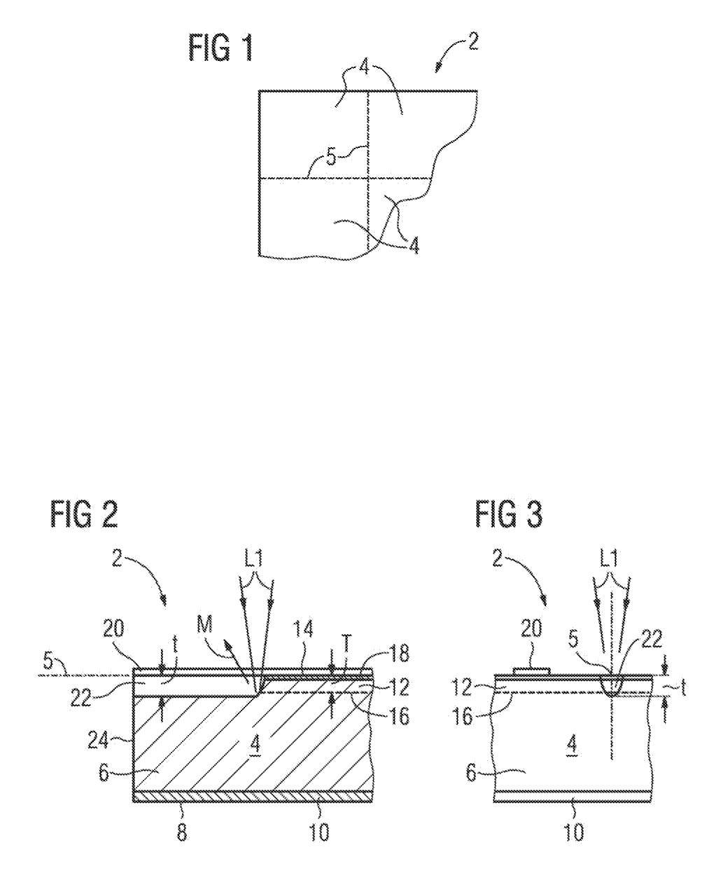

Referring now to the figures of the drawing in detail and first, particularly, to FIG. 1 thereof, there is shown a plurality of finished processed silicon solar cells 4 that are arranged in a silicon wafer 2, which silicon solar cells 4 are singulated, i.e. separated from one another, at predetermined separating lines 5 in a subsequent production step, explained below.

In accordance with FIGS. 2 and 3, the silicon wafer 2 is constructed from a p-doped silicon substrate 6 serving as a base, the silicon substrate is provided with a metallic base contact 10 on a rear side 8. An n-doped emitter layer 12 has been produced in the p-doped silicon substrate 6 by addition of an n-type dopant on the front side 14 lying opposite the rear side 8, the emitter layer being only a few μm thick, such that a pn junction 16 depicted in a dashed fashion is situated at a depth T amounting to only a few μm. The front side 14 of the silicon wafer 2 is additionally provided with an antireflection layer 18 and also with a plurality of emitter contacts 20.

In order to separate the silicon solar cells 4, in a first work step, a groove 22 is introduced (scribed) into the front side 14 of the silicon wafer 2, the front side being adjacent to the pn junction 16, by use of a first laser beam L1 along one of the separating lines 5 by a laser removal or laser ablation method, the depth t of the groove extending as least as far as the depth T of the pn junction 16, which is typically approximately 1 μm. In the example in FIGS. 2 and 3, the removal starts at a lateral edge 24 of the silicon wafer 2. However, in principle, the removal can also start at a location at a distance from the edge of the silicon wafer 2. What is essential, however, is that the completed groove 22 extends as far as the lateral edges 24 of the silicon wafer 2. The first laser beam L1 is pulsed, the pulse durations preferably being in the nanoseconds range and wavelengths in the range of between 200 nm-2,000 nm being used. In principle, shorter pulse durations below the nanoseconds range are also suitable. In this case, the depth t of the groove 22 exceeds the depth T of the pn junction preferably by a number of micrometers, for example by more than 10 μm. In practice, a depth of the groove 22 of approximately 12-15 μm has proved to be suitable.

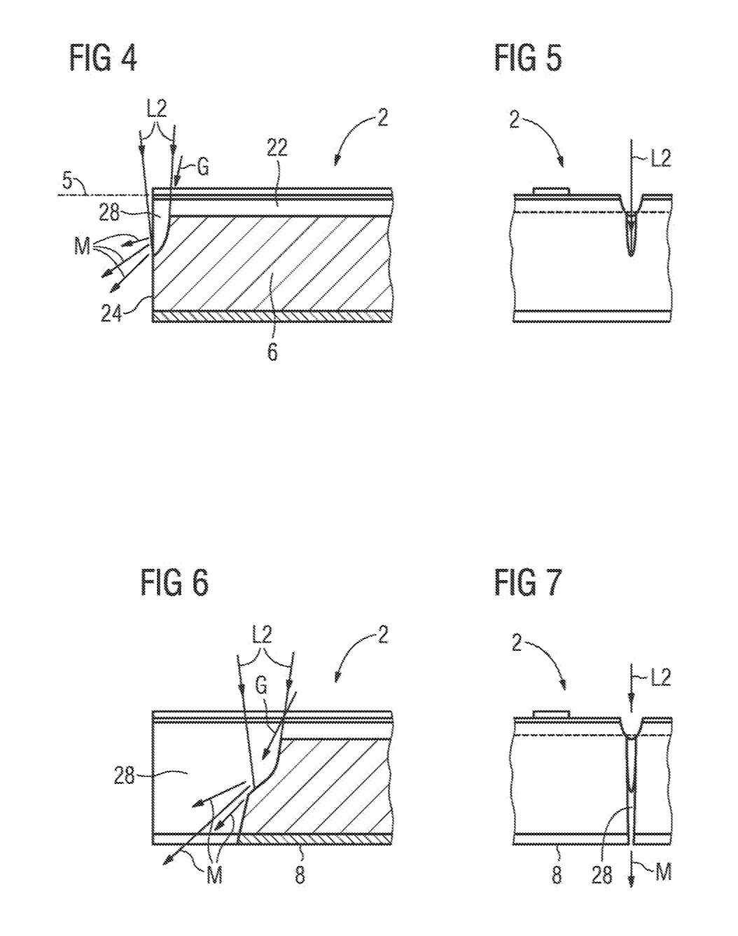

After completion of the groove 22, in accordance with FIGS. 4 and 5, in a second work step, the substrate 2 is cut along the separating line 5 starting at the lateral edge 24 by a second, preferably likewise pulsed, laser beam L2 directed into the groove 22. In this case, a melted material M arising during laser cutting is driven out of a cutting kerf 28 that arises at the start of laser cutting and does not yet reach as far as the rear side 8, laterally at the edge 24, i.e. with a flow component oriented in the direction of the second laser beam L2 and directed toward the rear side, by a cutting gas G flowing at high speed approximately in the direction of the second laser beam L2. This prevents a situation in which, during the melting of the base, i.e. of the p-doped region of the silicon substrate 6, a melting zone enriched with p-type dopant is formed which propagates as far as the n-doped side wall of the groove 22 and wets the latter. In other words: the melted material M enriched with p-type dopants does not come into contact with the n-doped emitter layer 12. The pulse durations of the second laser beam L2 are typically in the microseconds range, the wavelength of the second laser beam L2 preferably being in the near infrared range.

In accordance with FIGS. 6 and 7, the cutting kerf 28 reaches the rear side 8, such that a separating gap that is open toward the rear side 8 and propagates by the laser beam L2 being advanced in the direction of the separating line 5 arises, from which separating gap the melted material M can be driven out toward the rear side 8. The pn junction at the side walls of the separating gap is maintained in this way.

1. A method for separating silicon solar cells, which comprises the steps of:
introducing a groove into a silicon wafer containing the silicon solar cells via a first laser beam along a separating line into a front side of the silicon wafer, the front side being adjacent to a pn junction in the silicon wafer, the groove having a depth reaching at least as far as the pn junction, and the groove extending as far as a lateral edge of the silicon wafer; and
cutting the silicon wafer along the separating line starting at the lateral edge via a second laser beam directed into the groove, wherein melted material arising during the cutting is driven out of a cutting kerf arising during the cutting by means of a cutting gas flowing at least approximately in a direction of the second laser beam.

2. The method according to claim 1, wherein the first and second laser beams are pulsed, and a pulse duration of the first laser beam is shorter than a pulse duration of the second laser beam.
